(19) United States
(12) Patent Application Publication
(10) Pub. No.: US 2025/0251232 A1
(43) Pub. Date: Aug. 7, 2025

(54) METHODS AND SENSOR DEVICES FOR POSITION DETECTION

(71) Applicant: Infineon Technologies AG, Neubiberg (DE)

(72) Inventors: Joo Il PARK, Sungnam-Si (KR); Severin NEUNER, Valley (DE); Hyun Jeong KIM, Seoul (KR); Stephan LEISENHEIMER, Oberhaching (DE); Jakob VALTL, München (DE)

(21) Appl. No.: 18/986,313

(22) Filed: Dec. 18, 2024

(30) Foreign Application Priority Data
Dec. 23, 2023 (DE) 102023213325.3

(51) Int. Cl. G01B 7/004

(52) U.S. Cl. CPC G01B 7/004

(57) ABSTRACT

A method for determining a position of a magnetic field sensor in a plane defined by a first direction and a second direction perpendicular to the first direction includes an act of measuring, by the magnetic field sensor, a 3D magnetic field vector of a magnetic field generated by a magnet separated from the plane by an airgap, wherein the 3D magnetic field vector includes first, second, and third magnetic field components in respective first, second, and third directions. The method further includes determining a first displacement between the magnetic field sensor and the magnet in a first direction based on the first magnetic field component and the third magnetic field component. The method further includes determining a second displacement between the magnetic field sensor and the magnet in a second direction based on the second magnetic field component and the third magnetic field component.

### CROSS-REFERENCE TO RELATED APPLICATION

This application claims priority to Germany Patent Application No. 102023213325.3 filed on Dec. 23, 2023, the content of which is incorporated by reference herein in its entirety.

### TECHNICAL FIELD

The present disclosure relates to methods and sensor devices for position detection. More particular, the present disclosure relates to methods for determining a position of a magnetic field sensor in a plane and sensor devices for performing such methods.

### BACKGROUND

In many technical applications various components have to be positioned relative to each other as precisely as possible. For example, autonomous robots need to position themselves automatically at wireless charging stations. An efficiency of the charging process may be negatively affected if the robots are not positioned precisely enough in relation to the charging point.

Manufacturers and developers of sensor devices for positioning purposes are constantly striving to improve their products. In particular, it may be desirable to develop efficient and fast methods for determining the position of an object. In addition, it may be desirable to provide associated sensor devices for performing such methods.

### SUMMARY

An aspect of the present disclosure relates to a method for determining a position of a magnetic field sensor in a plane defined by a first direction and a second direction perpendicular to the first direction. The method includes an act of measuring, by the magnetic field sensor, a three-dimensional (3D) magnetic field vector of a magnetic field generated by a magnet separated from the plane by an airgap, wherein the 3D magnetic field vector includes a first magnetic field component in the first direction, a second magnetic field component in the second direction and a third magnetic field component in a third direction perpendicular to the first direction and the second direction. The method further includes an act of determining a first displacement between the magnetic field sensor and the magnet in the first direction based on the first magnetic field component and the third magnetic field component. The method further includes an act of determining a second displacement between the magnetic field sensor and the magnet in the second direction based on the second magnetic field component and the third magnetic field component.

A further aspect of the present disclosure relates to a sensor device. The sensor device includes a magnetic field sensor. The magnetic field sensor is configured to move in a plane defined by a first direction and a second direction perpendicular to the first direction. The magnetic field sensor is further configured to measure a 3D magnetic field vector of a magnetic field generated by a magnet separated from the plane by an airgap. The 3D magnetic field vector includes a first magnetic field component in the first direction, a second magnetic field component in the second direction and a third magnetic field component in a third direction perpendicular to the first direction and the second direction. The sensor device further includes a calculation unit. The calculation unit is configured to determine a first displacement between the magnetic field sensor and the magnet in the first direction based on the first magnetic field component and the third magnetic field component. The calculation unit is further configured to determine a second displacement between the magnetic field sensor and the magnet in the second direction based on the second magnetic field component and the third magnetic field component.

### BRIEF DESCRIPTION OF THE DRAWINGS

Methods and devices in accordance with the disclosure are described in more detail below based on the drawings. Similar reference numerals may designate corresponding similar parts. The technical features of the various illustrated examples may be combined, provided they are not mutually exclusive, and/or may be selectively omitted if not described as being necessarily required.

FIGS. 1A and 1B schematically illustrate a perspective view and a top view of a sensor device 100 in accordance with the disclosure.

FIG. 2 illustrates a flowchart of a method for determining a position of a magnetic field sensor in a plane in accordance with the disclosure.

FIGS. 3A to 3C schematically illustrate a perspective view and two side views of a magnetic field generated by a magnet.

FIGS. 4A and 4B illustrate a dependence between a first angle of a magnetic field vector and a first displacement between a magnetic field sensor and a magnet generating the magnetic field.

FIGS. 5A and 5B illustrate a dependence between a second angle of a magnetic field vector and a second displacement between a magnetic field sensor and a magnet generating the magnetic field.

FIGS. 6A to 6C schematically illustrate an example application of a method and a sensor device in accordance with the disclosure.

FIG. 7 schematically illustrates a top view of a sensor device 700 in accordance with the disclosure.

FIG. 8 schematically illustrates a side view of a sensor device 800 in accordance with the disclosure.

### DETAILED DESCRIPTION

The methods and sensor devices described herein may be used for determining a relative position between a magnetic field sensor and a magnet. An object may be mechanically coupled to the magnetic field sensor or the magnet such that a position of the object may be associated with the determined relative position of the magnetic field sensor and the magnet. The described methods and sensor devices are not restricted to one specific application, but may be used in a variety of applications. In one example, the methods and sensor devices may be used in a wireless charging act. In such act, the methods and sensor devices may be used by an autonomous robot for appropriately positioning itself relative to a wireless charging station. In a further example, the methods and sensor devices may be used in a headlight alignment act (e.g., of a car). In such act, a misalignment of an LED printed circuit board may be detected and adjusted. In yet another example, the methods and sensor devices may be used in a camera stabilization act. In such act, the methods and sensor devices may be used for an optical image stabilization, an autofocus and/or an optical zoom (e.g., of a cell phone). Here, a position of one or more lenses may be determined and used for their alignment.

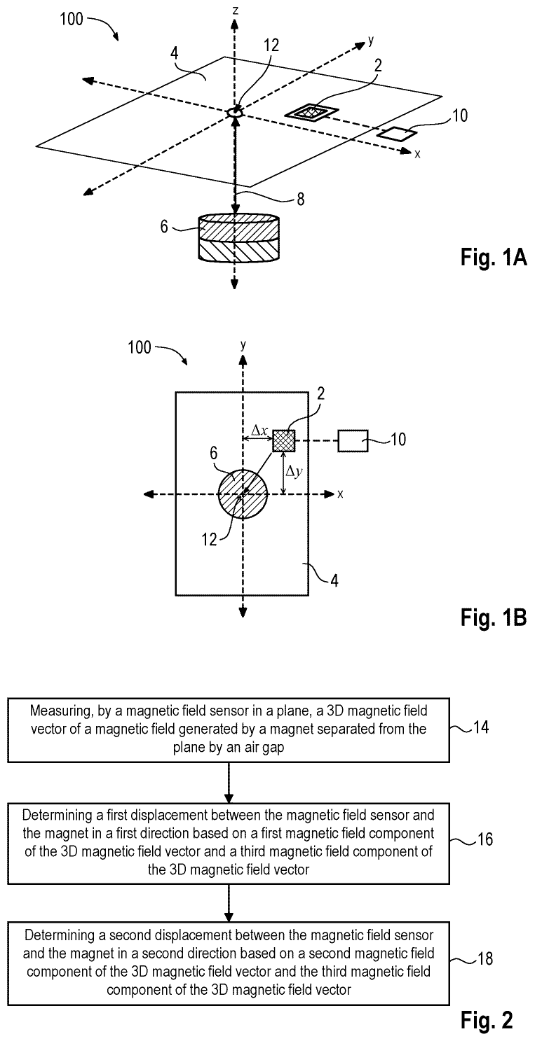

Referring now to FIG. 1, a plane defined by a first direction (x-direction) and a second direction (y-direction) perpendicular to the first direction is illustrated. A third direction (z-direction) may extend perpendicular to the first direction and the second direction. A sensor device 100 may include a magnetic field sensor 2 and a calculation unit 10 connected thereto. The calculation unit 10 may include one or more processors or processing circuit configured to process signals, evaluate the signals, perform calculations based on the signals, and/or generate outputs (e.g., output signals) as a result of the calculations (e.g., representative of calculation results). The magnetic field sensor 2 may be configured to move in the x-y-plane, more particular in a sector of the x-y-plane which may be referred to as range of motion 4. The sensor device 100 may further include a magnet 6 separated from the x-y-plane by an airgap 8. The magnet 6 may be seen as a part of the sensor device 100 or not.

In the illustrated example, the range of motion 4 of the magnetic field sensor 2 may have the shape of a rectangle. In further examples, the shape of the range of motion 4 may differ depending on the considered application. The range of motion 4 may e.g., measure about 10 mm in the x-direction and about 20 mm in the y-direction. However, these dimensions are in no way limiting and only given for illustrative purposes.

The magnet 6 may be positioned at a reference position directly under the origin of the illustrated coordinate system. That is, the magnet 6 may be arranged on a line extending perpendicular to the x-y-plane through the coordinate origin. For example, the magnet 6 may be axially magnetized in the z-direction. In this regard, the upper half of the magnet 6 may correspond to a magnetic north pole, while the lower half of the magnet 6 may correspond to a magnetic south pole, or vice versa.

The magnetic field sensor 2 may be configured to measure a 3D magnetic field vector of the magnetic field generated by the magnet 6. The measured 3D magnetic field vector may include three magnetic field components in the x-direction, y-direction and z-direction. The magnetic field sensor 2 may include one or multiple sensor elements which are not restricted to a specific sensing technology. For example, a sensor element of the magnetic field sensor 2 may be a Hall sensor element, a magnetoresistive sensor element, a vertical Hall sensor element, or a fluxgate sensor element. A magnetoresistive xMR sensor element may be an AMR (Anisotropic Magneto-Resistive) sensor element, a GMR (Giant Magneto-Resistive) sensor element, or a TMR (Tunnel Magneto-Resistive) sensor element. In one particular case, the magnetic field sensor 2 may include or correspond to a 3D Hall sensor. The magnetic field sensor 2 and its sensor elements may be included in a semiconductor chip.

Physical signals sensed by the magnetic field sensor 2 may be converted into electrical signals and may be forwarded to other components (e.g., the calculation unit 10) for further processing or evaluation. In the illustrated case, a connection between the magnetic field sensor 2 and the calculation unit 10 is only qualitatively indicated by a dashed line. In practice, the calculation unit 10 may be implemented in various forms. In one example, the calculation unit 10 may include a digital signal processor, wherein the digital signal processor and the magnetic field sensor 2 may be integrated in a same semiconductor chip. In a further example, the magnetic field sensor 2 may be included in a semiconductor chip and the calculation unit 10 may be included in a microcontroller external to the semiconductor chip.

In the top view of FIG. 1B, the magnetic field sensor 2 may be arranged offset to the coordinate origin and the magnet 6. In this regard, Δx may denote a first displacement between the magnetic field sensor 2 and the magnet 6 in the x-direction, while Δy may denote a second displacement between the magnetic field sensor 2 and the magnet 6 in the y-direction. A target position 12 of the magnetic field sensor 2 may be identified with the coordinate origin.

In some applications, it may be an objective to move the magnetic field sensor 2 to the target position 12. For example, autonomous robots may need to be recharged on a regular basis at a charging station located at a target position. In such case, the magnetic field sensor 2 may be mechanically coupled to the robot and the magnet 6 may be mechanically coupled to the charging station. For charging purposes, the position of the magnetic field sensor 2 (and thus the position of the robot) may be determined and based thereon the robot may be moved to the charging station.

Referring now to FIG. 2, a flowchart of a method in accordance with the disclosure is illustrated. The method is for determining a position of a magnetic field sensor in a plane defined by a first direction and a second direction perpendicular to the first direction. The method is described in a general manner in order to qualitatively specify aspects of the disclosure. For example, the method may be used for determining the position of the magnetic field sensor 2 in the example of FIG. 1. It is to be understood that the method may include further aspects. For example, the method may be extended by any of the aspects described in connection with other examples described herein.

At 14, the magnetic field sensor may measure a 3D magnetic field vector of a magnetic field generated by a magnet separated from the plane by an airgap. The 3D magnetic field vector may include a first magnetic field component in the first direction, a second magnetic field component in the second direction and a third magnetic field component in a third direction perpendicular to the first direction and the second direction. At 16, a first displacement between the magnetic field sensor and the magnet in the first direction may be determined based on the first magnetic field component and the third magnetic field component. At 18, a second displacement between the magnetic field sensor and the magnet in the second direction may be determined based on the second magnetic field component and the third magnetic field component. In the following, the method of FIG. 2 is described in more detail.

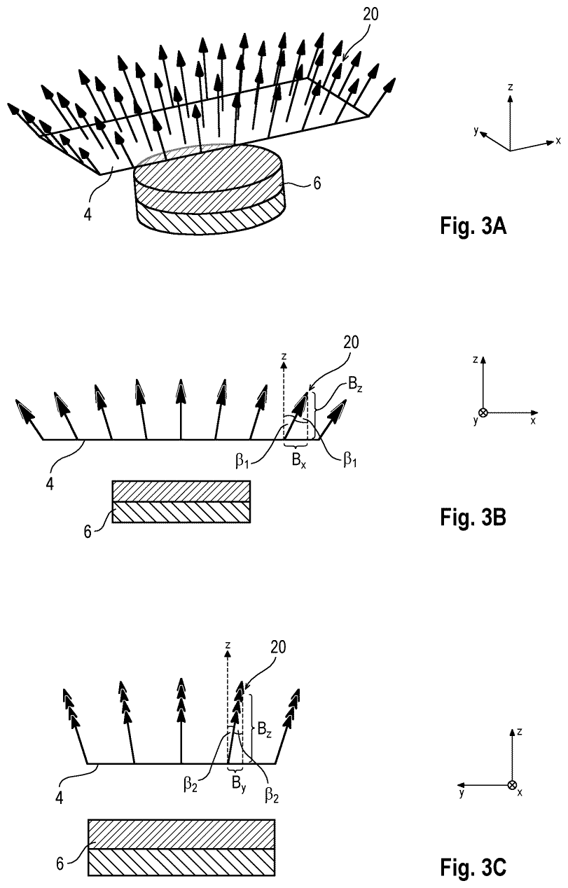

Referring now to FIG. 3A, the magnetic field generated by the axially magnetized magnet 6 in the range of motion 4 is schematically illustrated. More particular, a plurality of magnetic field vectors representing the magnetic field at multiple positions of the range of motion 4 is shown. FIG. 3B illustrates the magnetic field of FIG. 3A when viewed in the y-direction, while FIG. 3C illustrates the magnetic field of FIG. 3A when viewed in the x-direction.

An example 3D magnetic field vector 20 of the plurality of illustrated magnetic field vectors is now considered. In the side view of FIG. 3B, the 3D magnetic field vector 20 may be decomposed into its first magnetic field component Bₓ in the x-direction and its third magnetic field component B_{z} in the z-direction. A first angle β₁ between the 3D magnetic field vector 20 and the z-direction may be represented by a first arctangent value

$${β}_{1} = {tan}^{- 1} ( \frac{{B}_{x}}{{B}_{z}} ) \qquad ( 1 )$$

In the side view of FIG. 3C, the 3D magnetic field vector 20 may be decomposed into its second magnetic field component B_{y} in the y-direction and its third magnetic field component B_{z} in the z-direction. A second angle β₂ between the 3D magnetic field vector 20 and the z-direction may be represented by a second arctangent value

$${β}_{2} = {tan}^{- 1} ( \frac{{B}_{y}}{{B}_{z}} ) \qquad ( 2 )$$

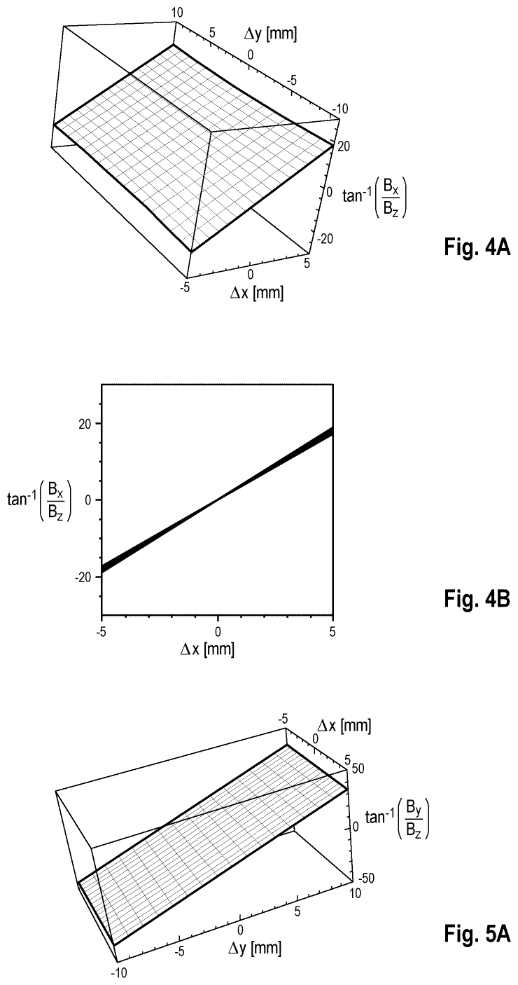

Each position of the magnetic field sensor 2 in the range of motion 4 may be specified by its displacement with respect to the target position 12, e.g., by a pair of values (Δx, Δy). FIG. 4A illustrates a dependence between the first angle β₁ (or the first arctangent value

$${tan}^{- 1} ( \frac{{B}_{x}}{{B}_{z}} ) )$$

and the position of the magnetic field sensor 2 (e.g., (Δx, Δy)) in the considered range of motion 4. That is, each position of the magnetic field sensor 2 in the range of motion 4 may be mapped to a value of the first angle β₁ and/or vice versa. For example, the dependence between the first angle β₁ and the position (Δx, Δy) may be obtained by measurements and/or simulation results. As can be seen from FIG. 4A, the dependence may be represented by a first quasi-plane (or substantially by a first plane).

FIG. 4B illustrates a dependence between the first angle β₁ and the x-position Δx of the magnetic field sensor 2 in the considered range of motion 4 for a fixed value of Δy. As can be seen from FIG. 4B, a first dependence between the first angle β₁ and the first displacement Δx may be quasi-linear (or substantially linear), e.g.,

$$Δ x = {k}_{x} {tan}^{- 1} ( \frac{{B}_{x}}{{B}_{z}} ) \qquad ( 3 )$$

wherein kₓ is a first proportionality factor corresponding to the slope of the (quasi) straight line shown in FIG. 4B. The factor kₓ may be determined in a calibration act described later on.

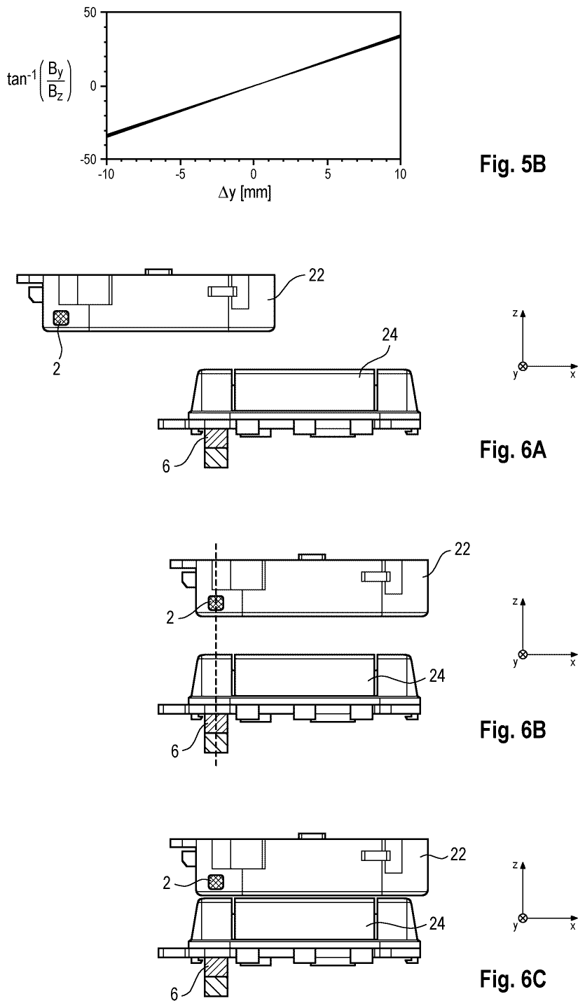

Similar to the previous discussion FIG. 5A illustrates a dependence between the second angle β₂ (or the second arctangent value

$${tan}^{- 1} ( \frac{{B}_{y}}{{B}_{z}} ) )$$

and the position of the magnetic field sensor 2 (e.g., (Δx, Δy)) in the considered range of motion 4. That is, each position of the magnetic field sensor 2 in the range of motion 4 may be mapped to a value of the second angle β₂ and/or vice versa. For example, the dependence between the second angle β₂ and the position (Δx, Δy) may be obtained by measurements and/or simulation results. As can be seen from FIG. 5A, the dependence may be represented by a second quasi-plane (or substantially by a second plane).

FIG. 5B illustrates a dependence between the second angle β₂ and the y-position Δy of the magnetic field sensor 2 in the considered range of motion 4 for a fixed value of Δx. As can be seen from FIG. 5B, a second dependence between the second angle β₂ and the second displacement Δy may be quasi-linear (or substantially linear), e.g.,

$$Δ y = {k}_{y} {tan}^{- 1} ( \frac{{B}_{y}}{{B}_{z}} ) \qquad ( 4 )$$

wherein k_{y} is a second proportionality factor corresponding to the slope of the (quasi) straight line of FIG. 5B. The factor k_{y} may be determined in a calibration act described later on.

It is to be noted that the range of motion 4 may be chosen such that the dependencies of FIGS. 4 and 5 are substantially linear. However, the dependencies between the angles (β₁, β₂) and the displacements (Δx, Δy) may not necessarily be linear (or quasi-linear) at positions outside of the range of motion 4.

Referring now back to the sensor device 100 of FIG. 1 and the method of FIG. 2, during an operation of the sensor device 100, the magnetic field sensor 2 may be located at a position (Δx, Δy) that is to be determined. In step 14, the magnetic field sensor 2 may measure the 3D magnetic field vector (Bₓ, B_{y}, B_{z}) of the magnetic field generated by the magnet 6 at the position (Δx, Δy). Any other interfering magnetic fields, such as e.g., stray fields, may be considered negligible herein. The obtained measurement signals may then be forwarded to the calculation unit 10 for further processing. In step 16, the calculation unit 10 may calculate the first displacement Δx using equation (3) based on the measured magnetic field components Bₓ and B_{z}. In step 18, the calculation unit 10 may calculate the second displacement Δy using equation (4) based on the measured magnetic field components B_{y} and B_{z}.

It is to be understood that the method of FIG. 2 may include one or more additional steps. Some example steps are specified in the following.

In an optional further step, at least one of the magnetic field sensor 2 or the magnet 6 may be moved to a common position based on the calculated displacements Δx and Δy. In this regard, the magnetic field sensor 2 may e.g., be moved to the target position 12 and arranged directly above the magnet 6.

In a further optional step, the magnetic field sensor 2 may be mechanically coupled to an object. The magnetic field sensor 2 and the object coupled thereto may move in the x-y-plane, while the magnet 6 may remain at its reference position. The position of the object may correspond to the position of the magnetic field sensor 2 and may thus be determined based on the calculated displacements Δx and Δy.

In a further optional step, the magnet 6 may be mechanically coupled to an object. In such case, the magnetic field sensor 2 may remain at a reference position, while the magnet 6 and the object coupled thereto may move in the x-y-plane. The magnetic field sensor 2 may measure the 3D magnetic field vector of the magnetic field generated by the magnet 6, and the calculation unit 10 may determine the displacements Δx and Δy as previously described. A transmission unit may (in particular wirelessly) transmit the determined displacements to at least one actuator (e.g., a motor). The actuator may receive the determined displacements from the transmission unit and may move the magnet 6 (and thus the object) based thereon. The transmission unit and the actuator may be seen as a part of the sensor device or not.

In a further optional step, the proportionality factors kₓ and k_{y} of equations (3) and (4) may be determined based on a one point calibration. In such calibration process, a non-zero position of the magnetic field sensor 2 may be chosen, e.g., a sensor position with an arbitrary non-zero first angle β₁ and an arbitrary non-zero second angle β₂. For the chosen non-zero position, the 3D magnetic field vector (Bₓ, B_{y}, B_{z}) and the displacements Δx and Δy may be measured. Using the measured magnetic field components, the angles β₁ and β₂ associated with the non-zero position may be calculated based on equations (1) and (2). In addition, as can be seen from FIGS. 4B and 5B, the values of the angles β₁ and β₂ are zero for displacement values Δx and Δy of zero. The proportionality factors kₓ and k_{y} may thus be determined based on the measurements for only one single non-zero position.

The previously described methods and sensor devices in accordance with the disclosure may outperform conventional concepts. In a first conventional concept, the 3D magnetic field data (Bₓ, B_{y}, B_{z}) may be matched to the positions around the magnet using a lookup table. Such solution may require a large amount of data to be stored and an extensive calibration in order to generate the lookup table. In a second conventional concept, a gradient descent algorithm may be used. Here, a sensor system may stepwise move towards the position of the strongest magnetic field. Such solution may be slow as it may require extensive calculations in multiple steps.

In contrast to such conventional techniques, a relative position between the magnetic field sensor 2 and the magnet 6 may be determined by a measurement of the 3D magnetic field vector (Bₓ, B_{y}, B_{z}) and a simple calculation of the displacements Δx and Δy based on equations (1) to (4). There is a simple linear mapping between the angles β₁, β₂ and the displacements Δx, Δy. The proportionality factors kₓ and k_{y} may be determined by a simple one point calibration as previously described. After having calculated the displacement values, the magnetic field sensor 2 may directly move to the target position 12. In short, the concepts described herein only require one calibration point (as compared to the lookup-table used in the first conventional solution) and only one simple calculation step (as compared to the multiple calculation steps of the second conventional solution).

Referring now to FIGS. 6A to 6C, an example application of the previously described methods and sensor devices in accordance with the disclosure is illustrated. More particular, a positioning of an autonomous robot relative to a wireless charging station is shown and discussed.

In FIG. 6A, an (in particular autonomous) robot 22 including a magnetic field sensor 2 and a charging station 24 including a magnet 6 is shown. The robot 22 may be configured to move in the x-y-plane and may be offset with respect to the charging station 24 by a first displacement Δx in the x-direction and a second displacement Δy in the y-direction.

In FIG. 6B, the magnetic field sensor 2 may measure a 3D magnetic field vector of the magnetic field generated by the magnet 6. A calculation unit (not illustrated) may determine the displacements Δx and Δy as previously described. Based thereon the robot 22 may move to a target position in which the magnetic field sensor 2 is arranged directly over the magnet 6.

In FIG. 6C, the robot 22 may move in the z-direction towards the charging station 24 such that a charging port of the robot 22 may connect to the charging station 24 and a process for charging the robot 22 may start.

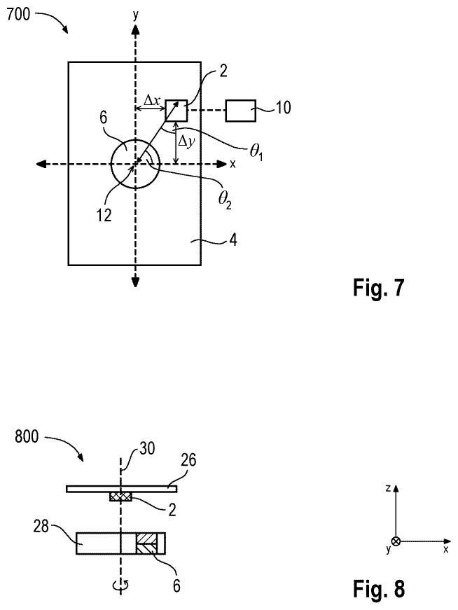

In addition to the above described position detection, the methods and sensor devices in accordance with the disclosure may be configured to measure a rotation or angular motion of a target. In this context, FIG. 7 illustrates a top view of a sensor device 700 in accordance with the disclosure. The sensor device 700 may include some or all features of the sensor device 100 of FIG. 1.

A magnetic field sensor 2 may be offset to a target position 12 by the displacements Δx and Δy as previously described. A first angular coordinate (or rotation angle) θ₁ of the magnetic field sensor 2 in the x-y-plane may be determined based on the displacements Δx and Δy by

$${θ}_{1} = {tan}^{- 1} ( \frac{Δ x}{Δ y} ) \qquad ( 5 a )$$

Alternatively, or additionally, a second angular coordinate (or rotation angle) θ₂ of the magnetic field sensor 2 in the x-y-plane may be determined based on

$${θ}_{2} = {tan}^{- 1} ( \frac{Δ y}{Δ x} ) = \frac{π}{2} - {θ}_{1} \qquad ( 5 b )$$

Based on the determined angular coordinate(s) a rotational movement of an object mechanically coupled to one of the magnetic field sensor 2 or the magnet 6 may be determined.

Referring now to FIG. 8, a sensor device 800 may include a printed circuit board 26 and a magnetic field sensor 2 arranged thereon. In addition, the sensor device 800 may include a magnet 6 which may be encapsulated in an encapsulation 28. The encapsulation 28 may be configured to rotate around a rotational axis 30 extending in the z-direction, wherein the magnet 6 may be offset to the rotational axis 30. A rotation of the encapsulation 28 around the rotational axis 30 may result in a movement of the magnet 6 along a circular curve. The magnetic field sensor 2 may be aligned with the rotational axis 30.

During a rotation of the encapsulation 28 and the magnet 6 embedded therein, the magnetic field sensor 2 may measure the 3D magnetic field vector of the magnetic field generated by the magnet 6. Angular coordinates may then be calculated by a calculation unit based on the measured magnetic field components and equations (5a) and/or (5b). The rotational movement and an angular position of the magnet 6 may be determined based on the calculated angular coordinates.

The concept described in connection with FIGS. 7 and 8 may be configured to determine a rotational movement and/or a rotation angle of an object mechanically coupled to the magnet 6 (or to the encapsulation 28), wherein a rotation of the object may be based on a rotation of the magnet 6. The object may be of arbitrary type. In one example, the object may include or may correspond to an automotive component. An automotive component may, for example, be a steering wheel of a vehicle, in particular a steering wheel of an electric power steering system. In a further example, the described concept may determine rotation angles of a valve or a component of a valve control system. In a further example, the object may include or may correspond to a windshield wiper or another component of a windshield wiper application. In still another example, rotation angles of a component of a clutch may be determined. In yet further examples, the object may include or may correspond to a rotary knob, a component of an (in particular electric or combustion) engine, a shaft, a wind meter, etc.

In one specific example, the concept described in connection with FIGS. 7 and 8 may be used in connection with a safety mechanism for functional safety, in particular automotive functional safety. The safety mechanism may be configured to detect a malfunction of an object performing a rotational movement. In this context, a rotation angle may be determined based on the described algorithm in accordance with the disclosure. In addition, the rotation angle may be determined based on a second different algorithm. The determined rotation angles may then be compared and/or used for safety plausibility checks.

### Aspects

In the following, methods for determining a position of a magnetic field sensor in a plane and sensor devices in accordance with the disclosure are described using aspects.

Aspect 1 is a method for determining a position of a magnetic field sensor in a plane defined by a first direction and a second direction perpendicular to the first direction, the method comprising: measuring, by the magnetic field sensor, a 3D magnetic field vector of a magnetic field generated by a magnet separated from the plane by an airgap, wherein the 3D magnetic field vector comprises a first magnetic field component in the first direction, a second magnetic field component in the second direction and a third magnetic field component in a third direction perpendicular to the first direction and the second direction; determining a first displacement between the magnetic field sensor and the magnet in the first direction based on the first magnetic field component and the third magnetic field component; and determining a second displacement between the magnetic field sensor and the magnet in the second direction based on the second magnetic field component and the third magnetic field component.

Aspect 2 is a method according to Aspect 1, wherein: determining the first displacement comprises calculating a first arctangent value based on the first magnetic field component and the third magnetic field component, and determining the second displacement comprises calculating a second arctangent value based on the second magnetic field component and the third magnetic field component.

Aspect 3 is a method according to Aspect 2, wherein: the first arctangent value represents a first angle between the 3D magnetic field vector and the third direction when viewed in the second direction, and the second arctangent value represents a second angle between the 3D magnetic field vector and the third direction when viewed in the first direction.

Aspect 4 is a method according to Aspect 3, wherein for a range of motion of the magnetic field sensor: a first dependence between the first angle and the first displacement is quasi-linear, and a second dependence between the second angle and the second displacement is quasi-linear.

Aspect 5 is a method according to one of the preceding Aspects, wherein: the first displacement is determined based on

$$Δ x = {k}_{x} {tan}^{- 1} ( \frac{{B}_{x}}{{B}_{z}} ) ,$$

wherein Δx is the first displacement, kₓ is a first proportionality factor, and Bₓ and B_{z} are the first magnetic field component and the third magnetic field component, respectively, and the second displacement is determined based on

$$Δ y = {k}_{y} {tan}^{- 1} ( \frac{{B}_{y}}{{B}_{z}} ) ,$$

wherein Δy is the second displacement, k_{y} is a second proportionality factor, and B_{y} and B_{z} are the second magnetic field component and the third magnetic field component, respectively.

Aspect 6 is a method according to Aspect 5, further comprising: determining the first proportionality factor and the second proportionality factor based on a one point calibration.

Aspect 7 is a method according to Aspect 5 or 6, wherein determining the first proportionality factor and the second proportionality factor comprises: measuring the first displacement and the second displacement for a non-zero sensor position with a non-zero first angle and a non-zero second angle, measuring the 3D magnetic field vector for the non-zero sensor position, and determining the first proportionality factor and the second proportionality factor based on the measured 3D magnetic field vector and the two measured displacements.

Aspect 8 is a method according to one of the preceding Aspects, further comprising: moving at least one of the magnetic field sensor or the magnet to a common position based on the first displacement and the second displacement, wherein the magnetic field sensor is arranged directly above the magnet.

Aspect 9 is a method according to one of the preceding Aspects, further comprising: mechanically coupling the magnetic field sensor to an object, and determining a position of the object based on the first displacement and the second displacement.

Aspect 10 is a method according to one of Aspects 1 to 8, further comprising: mechanically coupling the magnet to an object, and determining a position of the object based on the first displacement and the second displacement.

Aspect 11 is a method according to one of the preceding Aspects, further comprising: determining an angular coordinate of the magnetic field sensor in the plane based on the first displacement and the second displacement.

Aspect 12 is a method according to Aspect 11, wherein determining the angular coordinate is based on

$$θ = {tan}^{- 1} ( \frac{Δ x}{Δ y} ) ,$$

wherein θ is the angular coordinate, and Δx and Δy are the first displacement and the second displacement, respectively.

Aspect 13 is a method according to Aspect 11 or 12, further comprising: determining a rotational movement of an object mechanically coupled to the magnet based on the angular coordinate.

Aspect 14 is a method according to one of the preceding Aspects, wherein the method is configured for being performed in a wireless charging act, a headlight alignment act, or a camera stabilization act.

Aspect 15 is a sensor device, comprising: a magnetic field sensor configured to: move in a plane defined by a first direction and a second direction perpendicular to the first direction, and measure a 3D magnetic field vector of a magnetic field generated by a magnet separated from the plane by an airgap, wherein the 3D magnetic field vector comprises a first magnetic field component in the first direction, a second magnetic field component in the second direction and a third magnetic field component in a third direction perpendicular to the first direction and the second direction; and a calculation unit configured to: determine a first displacement between the magnetic field sensor and the magnet in the first direction based on the first magnetic field component and the third magnetic field component, and determine a second displacement between the magnetic field sensor and the magnet in the second direction based on the second magnetic field component and the third magnetic field component.

Aspect 16 is a sensor device according to Aspect 15, wherein the magnetic field sensor is included in a semiconductor chip and the calculation unit is included in a microcontroller external to the semiconductor chip.

Aspect 17 is a sensor device according to Aspect 15, wherein the calculation unit comprises a digital signal processor, wherein the digital signal processor and the magnetic field sensor are integrated in a same semiconductor chip.

Aspect 18 is a sensor device according to one of Aspects 15 to 17, further comprising: a transmission unit configured to transmit the determined first displacement and second displacement (e.g., the determined first displacement and the second displacement determined by the calculation unit); and at least one actuator configured to receive the determined first displacement and second displacement from the transmission unit and move the magnet based on the determined first displacement and the determined second displacement.

Aspect 19 is a sensor device according to one of Aspects 15 to 18, wherein the magnet is axially magnetized in the third direction.

Aspect 20 is a sensor device according to one of Aspects 15 to 19, wherein the magnetic field sensor comprises a 3D Hall sensor.

While the present disclosure has been described with reference to illustrative aspects, this description is not intended to be construed in a limiting sense. Various modifications and combinations of the illustrative aspects, as well as other aspects of the disclosure, will be apparent to persons skilled in the art upon reference of the description. It is therefore intended that the appended claims encompass any such modifications or aspects.

1. A method for determining a position of a magnetic field sensor in a plane defined by a first direction and a second direction perpendicular to the first direction, the method comprising:
measuring, by the magnetic field sensor, a three-dimensional (3D) magnetic field vector of a magnetic field generated by a magnet separated from the plane by an airgap, wherein the 3D magnetic field vector comprises a first magnetic field component in the first direction, a second magnetic field component in the second direction, and a third magnetic field component in a third direction perpendicular to the first direction and the second direction;
determining a first displacement between the magnetic field sensor and the magnet in the first direction based on the first magnetic field component and the third magnetic field component; and
determining a second displacement between the magnetic field sensor and the magnet in the second direction based on the second magnetic field component and the third magnetic field component.

2. The method of claim 1, wherein:
determining the first displacement comprises calculating a first arctangent value based on the first magnetic field component and the third magnetic field component, and
determining the second displacement comprises calculating a second arctangent value based on the second magnetic field component and the third magnetic field component.

3. The method of claim 2, wherein:
the first arctangent value represents a first angle between the 3D magnetic field vector and the third direction when viewed in the second direction, and
the second arctangent value represents a second angle between the 3D magnetic field vector and the third direction when viewed in the first direction.

4. The method of claim 3, wherein for a range of motion of the magnetic field sensor:
a first dependence between the first angle and the first displacement is quasi-linear, and
a second dependence between the second angle and the second displacement is quasi-linear.

5. The method of claim 1, wherein:
the first displacement is determined based on
$$Δ x = {k}_{x} {tan}^{- 1} ( \frac{{B}_{x}}{{B}_{z}} )$$
wherein Δx is the first displacement, kₓ is a first proportionality factor, and Bₓ and B_{z} are the first magnetic field component and the third magnetic field component, respectively, and
the second displacement is determined based on
$$Δ y = {k}_{y} {tan}^{- 1} ( \frac{{B}_{y}}{{B}_{z}} )$$
wherein Δy is the second displacement, k_{y} is a second proportionality factor, and B_{y} and B_{z} are the second magnetic field component and the third magnetic field component, respectively.

6. The method of claim 5, further comprising:
determining the first proportionality factor and the second proportionality factor based on a one point calibration.

7. The method of claim 5, wherein determining the first proportionality factor and the second proportionality factor comprises:
measuring the first displacement and the second displacement for a non-zero sensor position with a non-zero first angle and a non-zero second angle,
measuring the 3D magnetic field vector for the non-zero sensor position, and
determining the first proportionality factor and the second proportionality factor based on the measured 3D magnetic field vector and the two measured displacements.

8. The method of claim 1, further comprising:
moving at least one of the magnetic field sensor or the magnet to a common position based on the first displacement and the second displacement, wherein the magnetic field sensor is arranged directly above the magnet.

9. The method of claim 1, further comprising:
mechanically coupling the magnetic field sensor to an object, and
determining a position of the object based on the first displacement and the second displacement.

10. The method of claim 1, further comprising:
mechanically coupling the magnet to an object, and
determining a position of the object based on the first displacement and the second displacement.

11. The method of claim 1, further comprising:
determining an angular coordinate of the magnetic field sensor in the plane based on the first displacement and the second displacement.

12. The method of claim 11, wherein determining the angular coordinate is based on:
$$θ = {tan}^{- 1} ( \frac{Δ x}{Δ y} )$$
wherein θ is the angular coordinate, and Δx and Δy are the first displacement and the second displacement, respectively.

13. The method of claim 11, further comprising:
determining a rotational movement of an object mechanically coupled to the magnet based on the angular coordinate.

14. The method of claim 1, wherein the method is configured for being performed in a wireless charging act, a headlight alignment act, or a camera stabilization act.

15. A sensor device, comprising:
a magnetic field sensor configured to:
move in a plane defined by a first direction and a second direction perpendicular to the first direction, and
measure a three-dimensional (3D) magnetic field vector of a magnetic field generated by a magnet separated from the plane by an airgap,
wherein the 3D magnetic field vector comprises a first magnetic field component in the first direction, a second magnetic field component in the second direction, and a third magnetic field component in a third direction perpendicular to the first direction and the second direction; and
a calculation unit configured to:
determine a first displacement between the magnetic field sensor and the magnet in the first direction based on the first magnetic field component and the third magnetic field component, and
determine a second displacement between the magnetic field sensor and the magnet in the second direction based on the second magnetic field component and the third magnetic field component.

16. The sensor device of claim 15, wherein the magnetic field sensor is included in a semiconductor chip and the calculation unit is included in a microcontroller external to the semiconductor chip.

17. The sensor device of claim 15, wherein the calculation unit comprises a digital signal processor, and
wherein the digital signal processor and the magnetic field sensor are integrated in a same semiconductor chip.

18. The sensor device of claim 15, further comprising:
a transmission unit configured to transmit the first displacement and the second displacement determined by the calculation unit; and
at least one actuator configured to receive the first displacement and the second displacement from the transmission unit, and move the magnet based on the first displacement and the second displacement.

19. The sensor device of claim 15, wherein the magnet is axially magnetized in the third direction.

20. The sensor device of claim 15, wherein the magnetic field sensor comprises a 3D Hall sensor.
